(19) United States
(12) Patent Application Publication
(10) Pub. No.: US 2014/0113118 A1
(43) Pub. Date: Apr. 24, 2014

(54) HALOGEN-FREE RESIN COMPOSITION AND APPLICATION THEREOF

(71) Applicant: ELITE ELECTRONIC MATERIAL (KUNSHAN) CO., LTD, Jiangsu Province (CN)

(72) Inventors: RONG-TAO WANG, Jiangsu Province (CN); CHEN-YU HSIEH, Tao-Yuan Hsien (TW); ZIQIAN MA, Jiangsu Province (CN); WENJUN TIAN, Jiangsu Province (CN); WENFENG LU, Jiangsu Province (CN)

(73) Assignee: ELITE ELECTRONIC MATERIAL (KUNSHAN) CO., LTD, Jiangsu Province (CN)

(21) Appl. No.: 13/739,428

(22) Filed: Jan. 11, 2013

(30) Foreign Application Priority Data
Oct. 24, 2012 (CN) 201210410056.5

(51) Int. Cl. H05K 1/03; C09D 171/08

(52) U.S. Cl. CPC H05K 1/0353; C09D 171/08
USPC 428/209; 524/525; 524/502; 428/463

(57) ABSTRACT

A halogen-free resin composition including (A) 100 parts by weight of polyphenylene ether resin containing an alkenyl group; (B) 10 to 50 parts by weight of cyclo olefin copolymer (COC); (C) 5 to 50 parts by weight of 1,2,4-trivinylcyclohexane resin and/or 1,3,5-triethyloxymethyl cyclohexane resin; and (D) 5 to 150 parts by weight of polyphenylene ether pre-polymerized branch cyanate ester. The halogen-free resin composition can manifest low dielectric constant, low dielectric dissipation factor, high heat resistance, and high glass transition temperature by using the specified ingredient in the specified ratio, thus can be used in preparing a prepreg or a resin film, which is applicable to copper clad laminates and printed circuit boards.

### CROSS-REFERENCE TO RELATED APPLICATION

This non-provisional application claims priority under 35 U.S.C. §119(a) on Patent Application No(s). 201210410056.5 filed in China on Oct. 24, 2012, the entire contents of which are hereby incorporated by reference.

### FIELD OF THE INVENTION

The present invention relates to halogen-free resin compositions, and more particularly, to a halogen-free resin composition applicable to copper clad laminates, and printed circuit boards.

### BACKGROUND OF THE INVENTION

To get in line with the global trend of environmental protection, and eco-friendly regulations, electronic product manufacturers nowadays are developing, and manufacturing halogen-free electronic products. Advanced countries, and electronic manufacturing giants set forth schedules of launching mass production of halogen-free electronic products. As a result of the promulgation of the Restriction of Hazardous Substances (RoHS) by the European Union, hazardous substances, such as lead, cadmium, mercury, hexavalent chromium, poly-brominated biphenyl (PBB), and poly-brominated diphenyl ether (PBDE), are strictly prohibited from being used in manufacturing electronic products or their parts, and components. A printed circuit board (PCB) is an indispensable, and fundamental basis of the semiconductor industry, and electronic industry; hence, printed circuit boards bore the brunt of international halogen-free regulations when international organizations set forth strict requirements of the halogen content of printed circuit boards. For example, the International Electrotechnical Commission (IEC) 61249-2-21 requires that bromide content, and chloride content shall be less than 900 ppm, and the total halogen content shall be less than 1500 ppm. The Japan Electronics Packaging, and Circuits Association (JPCA) requires that both bromide content, and chloride content shall be less than 900 ppm. To enforce its green policies, Greenpeace calls on manufacturers worldwide to get rid of polyvinyl chloride (PVC), and brominated flame retardants (BFRs) from their electronic products in order to conform with the lead-free, and halogen-free requirements of green electronics. Hence, the industrial sector nowadays is interested in rendering related materials halogen-free, and sees this technique as one of its key research topics.

Electronic products nowadays have the trend toward compactness, and high-frequency transmission; hence, circuit boards nowadays typically feature a high-density layout, and increasingly strict material requirements. To mount high-frequency electronic components on a circuit board, it is necessary that the substrate of the circuit board is made of a material of a low dielectric constant (Dk), and dielectric dissipation factor (Df) in order to maintain the transmission speed, and the integrity of a signal transmitted. To allow the electronic components to operate well at a high temperature, and a high-humidity environment, it is necessary for the circuit board to be heat resistant, fire resistant, and of low hygroscopicity. Epoxy resin is adhesive, heat resistant, and malleable, and thus is widely applicable to encapsulants, and copper clad laminates (CCL) of electronic components, and machinery. From the perspective of fire prevention, and safety, any applicable material is required to be capable of flame retardation. In general, epoxy resin is incapable of flame retardation, and thus epoxy resin has to acquire flame retardation capability by including a flame retardant therein. For example, a halogen, especially bromine, is included in epoxy resin to bring about flame retardation capability of epoxy resin, and enhance the reactivity of the epoxy group. Furthermore, when exposed to a high temperature for a long period of time, a halogen compound is likely to decompose, and thereby erode a fine circuit. Furthermore, combustion of discarded used electronic parts, and components produces hazardous compounds, such as halogen compounds, which are environmentally unfriendly. To find an alternative to the aforesaid halogen compound-based flame retardant, researchers attempt to use a phosphorous compound as a flame retardant, for example, adding phosphate ester (U.S. Pat. No. 6,440,567) or red phosphorus (EP 0763566) to an epoxy resin composition. However, phosphate ester undergoes hydrolysis readily to produce an acid, thereby compromising its tolerance to migration. Although red phosphorus is good at flame retardation, it falls into the category of hazardous compounds under the firefighting law, because it produces a trace of a flammable, toxic gas known as phosphine in a warm humid environment.

A conventional circuit board manufacturing method, such as a conventional method of manufacturing a copper-clad substrate (also known as copper clad laminate, CCL), involves heating, and combining a reinforcement material (such as a glass fabric), and a thermosetting resin composition made of an epoxy resin and a curing agent to form a prepreg, and then laminating the prepreg, and the upper, and lower copper foils together at a high temperature, and a high pressure. The prior art usually teaches using a thermosetting resin composed of an epoxy resin, and a hydroxyl (—OH)-containing phenol novolac resin curing agent. Due to the combination of the phenol novolac resin and the epoxy resin, epoxide ring-opening reactions end up with another hydroxyl which not only increases the dielectric constant (Dk), and the dielectric dissipation factor inherently, but also reacts with water readily, and thereby renders the thermosetting resin more hygroscopic.

U.S. Pat. No. 7,255,925 discloses a thermosetting resin composition composed of cyanate resin, dicyclopentadiene (DCPD) epoxy resin, silica, and a thermoplastic resin. The thermosetting resin composition is characterized by a low dielectric constant (Dk), and a low dielectric dissipation factor. However, a method for manufacturing the thermosetting resin composition of U.S. Pat. No. 7,255,925 requires the use of a halogen-containing (such as bromine-containing) flame retardant, such as tetrabromocyclohexane, hexabromocyclodecane, or 2,4,6-tri(tribromophenoxy)-1,3,5-triazine. However, the bromine-containing flame retardant causes environmental pollution readily during the thermosetting resin composition manufacturing process, the using processing of thermosetting resin composition, and even after the thermosetting resin composition has been discarded or recycled. To ensure a low dielectric dissipation factor, low hygroscopicity, high cross-linking density, high glass transition temperature, high connectivity, appropriate thermal expansion, heat resistance, and fire resistance of copper clad laminates, an important factor lies in the selection of an epoxy resin, a curing agent, and a reinforcement material.

The major considerations given to electrical properties include the dielectric constant (Dk), and the dielectric dissipation factor. In general, the signal transmission speed of a copper-clad substrate is inversely proportional to the square root of the dielectric constant (Dk) of the material from which the copper-clad substrate is made, and thus the minimization of the dielectric constant (Dk) of the substrate material is usually advantageously important. The lower the dielectric dissipation factor is, the lesser the signal transmission attenuation is; hence, a material of a low dielectric dissipation factor provides satisfactory transmission quality.

Accordingly, it is important for printed circuit board material suppliers to develop materials of a low dielectric constant (Dk), a low dielectric dissipation factor, high heat resistance, and high glass transition temperature, and apply the materials to high-frequency printed circuit board manufacturing.

### SUMMARY OF THE INVENTION

In view of the aforesaid drawbacks of the prior art, the inventor of the present invention conceived room for improvement in the prior art, and thus conducted extensive researches, and experiments according to the inventor's years of experience in the related industry, and finally developed a halogen-free resin composition as disclosed in the present invention to achieve a low dielectric constant (Dk), a low dissipation factor (Df), high heat resistance, and high flame retardation.

It is an objective of the present invention to provide a halogen-free resin composition having the specified ingredient in the specified ratio so as to achieve a low dielectric constant (Dk), a low dielectric dissipation factor (Df), high heat resistance, and high glass transition temperature. The halogen-free resin composition is suitable for producing a prepreg or a resin film, and thus applicable to copper clad laminates, and printed circuit boards.

In order to achieve the above and other objectives, the present invention provides a halogen-free resin composition comprising: (A) 100 parts by weight of a polyphenylene ether resin containing an alkenyl group; (B) 10 to 50 parts by weight of a cyclo olefin copolymer (COC); (C) 5 to 50 parts by weight of a 1,2,4-trivinylcyclohexane resin and/or 1,3,5-triethyloxymethyl cyclohexane resin; and (D) 5 to 150 parts by weight of a polyphenylene ether pre-polymerized branch cyanate ester.

The ingredient (A) polyphenylene ether resin containing an alkenyl group in the halogen-free resin composition of the present invention is one of the compounds having structures of the following Formula 1, Formula 2, and Formula 3, or the combination thereof:

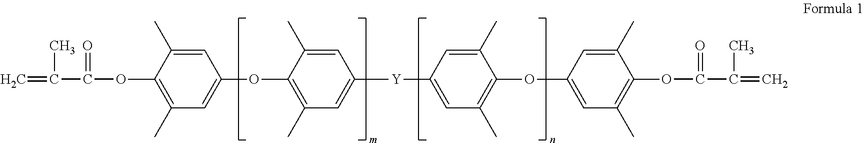

wherein Y is

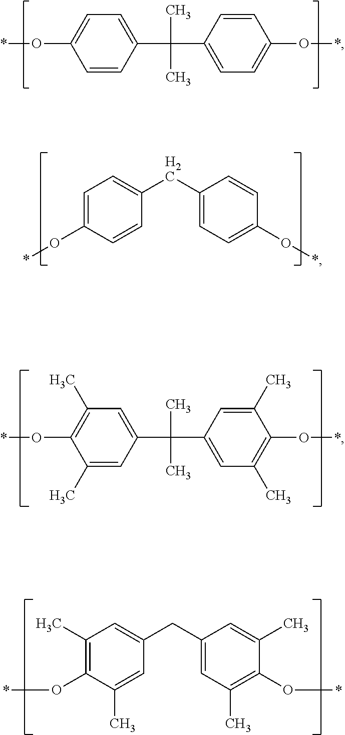

or a covalent bond; m and n independently represent an integer of 1 or more;

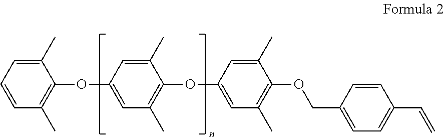

wherein n represents an integer of 6 to 80;

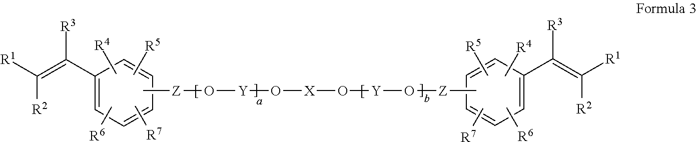

wherein a and b independently represent an integer of 0 to 30, provided that at least one of a and b is not zero; R¹, R², R³, R⁴, R⁵, R⁶, and R⁷ independently represent a hydrogen atom, a halogen atom, or an alkyl or phenyl group; Z represents an organic group containing at least one carbon atom; —(O—X—O)— represents a group having a structure of Formula 4 or Formula 5;

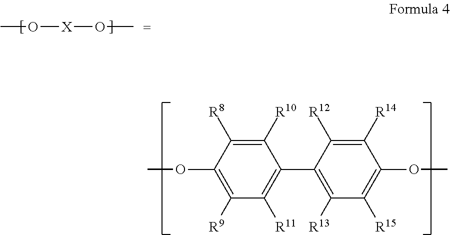

wherein R⁸, R⁹, R¹⁰, R¹⁴ and R¹⁵ independently represent a halogen atom, an alkyl group containing six or less carbon atoms, or a phenyl group; R¹¹, R¹² and R¹³ independently represent a hydrogen atom, a halogen atom, an alkyl group containing six or less carbon atoms, or a phenyl group.

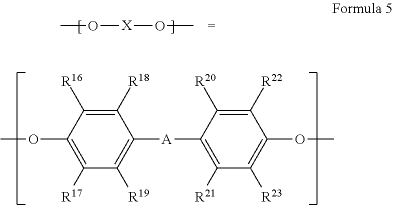

wherein R¹⁶, R¹⁷, R²² and R²³ independently represent a halogen atom, an alkyl group containing six or less carbon atoms, or a phenyl group; R¹⁸, R¹⁹, R²⁰, and R²¹ independently represent a hydrogen atom, a halogen atom, an alkyl group containing six or less carbon atoms, or a phenyl group; A represents a linear, branched, or cyclic hydrocarbon residue containing 20 or less carbon atoms;

—(Y—O)— represents a moiety having a structure of Formula 6 or any rearranged structure thereof;

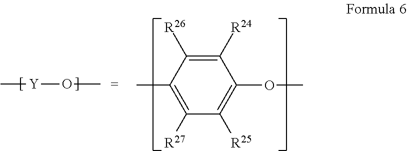

wherein R²⁴ and R²⁵ independently represent a halogen atom, an alkyl group containing six or less carbon atoms, or a phenyl group; R²⁶ and R²⁷ independently represent a hydrogen atom, a halogen atom, an alkyl group containing six or less carbon atoms, or a phenyl group.

Specifically speaking, for example, the compound expressed by Formula 1 is a product known by the brand name SA9000 and marketed by SABIC Innovative Plastics. For example, the compound expressed by Formula 2 is a product known by the brand name PP-600, marketed by CHIN YEE Chemical Industres Co., LTD., and manufactured by the reaction between the product known by the brand name SA-120 marketed by SABIC Innovative Plastics and

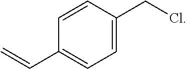

For example, the compound expressed by Formula 3 is a specific compound disclosed by an embodiment of U.S. Pat. No. 7,193,019.

The ingredient (B) cyclo olefin copolymer (COC) in the halogen-free resin composition of the present invention has a structure as follows:

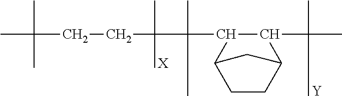

wherein X and Y independently represent an integer of 1 or more.

Specifically speaking, for example, the ingredient (B) cyclo olefin copolymer (COC) is a product known by the brand name Topas 5013, Topas 6017, Topas 8007, or Topas 6015.

The ingredient (C) in the halogen-free resin composition of the present invention is 1,2,4-trivinylcyclohexane resin or 1,3,5-triethyloxymethyl cyclohexane resin.

The ingredient (D) cyanate ester in the halogen-free resin composition of the present invention has a structure as follows:

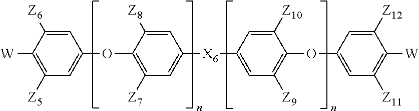

wherein X₆ represents a covalent bond, —SO₂—, —C(CH₃)₂—, —CH(CH₃)— or —CH₂—; Z₅ to Z₁₂ independently represent hydrogen or methyl; W represents —O—C≡N; n represents an integer larger than or equal to 1.

The halogen-free resin composition of the present invention further comprises at least one selected from the group consisting of a flame retardant, an inorganic filler, an initiator, a polymerization inhibitor, and an organic solvent.

The flame retardant comprises a phosphate compound and/or a nitrogen-containing phosphate compound, but is not limited thereto. Given 100 parts by weight of polyphenylene ether resin containing an alkenyl group, the amount of the flame retardant is 10 to 250 parts by weight.

Specifically speaking, the flame retardant preferably comprises at least one of bisphenol diphenyl phosphate, ammonium polyphosphate, hydroquinone bis-(diphenyl phosphate), bisphenol A bis-(diphenylphosphate), tri(2-carboxyethyl) phosphine (TCEP), tri(isopropyl chloride) phosphate, trimethyl phosphate (TMP), dimethyl methyl phosphonate (DMMP), resorcinol dixylenylphosphate (RDXP, such as PX-200), melamine polyphosphate, Phosphazene, 9,10-dihydro-9-oxa-10-phosphaphenanthrene-10-oxide (DOPO) and its derivatives or resins, melamine cyanurate, and tri-hydroxy ethyl isocyanurate, but is not limited thereto. For example, flame retardant can be DOPO compound, DOPO resin (such as DOPO-HQ, DOPO-PN, and DOPO-BPN), DOPO-bonded epoxy resin, wherein DOPO-BPN can be bisphenol novolac, such as DOPO-BPAN, DOPO-BPFN, and DOPO-BPSN.

The inorganic filler comprises at least one of: silicon dioxide (existing in a molten state or a non-molten state, or featuring a porous structure or a hollow-core structure), aluminum oxide, aluminum hydroxide, magnesium oxide, magnesium hydroxide, calcium carbonate, aluminum nitride, boron nitride, aluminum silicon carbide, silicon carbide, sodium carbonate, titanium dioxide, zinc oxide, zirconium oxide, quartz, diamond powder, diamond-like powder, graphite, magnesium carbonate, potassium titanate, ceramic fiber, mica, boehmite (AlOOH), zinc molybdate, ammonium molybdate, zinc borate, calcium phosphate, calcinated talc, talc, silicon nitride, mullite, calcinated kaolin clay, clay, basic magnesium sulfate whisker, mullite whisker, barium sulfate, magnesium hydroxide whisker, magnesium oxide whisker, calcium oxide whisker, carbon nanotube, nano silicon oxide, and its related inorganic powder or powder particles having an organic core and a shell modified by an insulator.

The inorganic filler comes in the form of a spherical shape, a fiber-like shape, board-like shape, particulate shape, strip-like shape, or needle-like shape, and is selectively pre-treated with a silane coupling agent.

The inorganic filler can be in the form of particulate powder of a diameter of 100 μm or less, or preferably a diameter of 1 μm to 20 μm, or most preferably nanoscale particulate powder of a diameter of 1 μm or less. The needle-shaped inorganic filler is in the form of powder, whose particles each having a diameter of 50 μm or less and a length of 1 to 200 μm.

The organic solvent comprises at least one of: methanol, ethanol, ethylene glycol monomethyl ether, acetone, butanone(methyl ethyl ketone), methyl isobutyl ketone, cyclohexanone, toluene, xylene, methoxyethyl acetate, ethoxyethyl acetate, propoxyethyl acetate, ethyl acetate, dimethyl formamide, dimethyl acetamide, propylene glycol methyl ether.

An objective of the present invention is to provide a prepreg. The prepreg has a low dielectric constant, a low dielectric dissipation factor, high glass transition temperature, high heat resistance, and halogen-free characteristics. Accordingly, the prepreg of the present invention comprises a reinforcement material and the aforesaid halogen-free resin composition, wherein the halogen-free resin composition is attached to the reinforcement material by means of impregnation, and heated up at a high temperature to be semi-cured. The reinforcement material, which is a fibrous material, a woven fabric, or a non-woven fabric, such as a glass fiber fabric, enhances the mechanical strength of the prepreg. Furthermore, the reinforcement material is selectively pretreated with a silane coupling agent or a siloxane coupling agent. For example, the reinforcement material is a glass fiber fabric pretreated with a silane coupling agent.

Another objective of the present invention is to provide a copper clad laminate. The copper clad laminate has a low dielectric constant, a low dielectric dissipation factor, high glass transition temperature, high heat resistance, and halogen-free characteristics, and is especially applicable to a circuit board for use in high-speed and high-frequency signal transmission. Accordingly, the present invention provides a copper clad laminate that comprises two or more copper foils and at least an insulating layer. The copper foils are metal alloy made of copper and at least one of aluminum, nickel, platinum, silver, and gold. The insulating layer is formed by curing the aforesaid prepreg at a high temperature and a high pressure. For example, the aforesaid prepreg is sandwiched between the two copper foils, and then the two copper foils and the prepreg therebetween are laminated against each other at a high temperature and a high pressure.

Yet another objective of the present invention is to provide a printed circuit board. The printed circuit board has a low dielectric constant, a low dielectric dissipation factor, high glass transition temperature, high heat resistance, and halogen-free characteristics, and is applicable to high-speed and high-frequency signal transmission. The circuit board comprises at least one of the copper clad laminates.

To further disclose the present invention and enable persons skilled in the art to implement the present invention accordingly. The present invention is disclosed below by several preferred embodiments. However, persons skilled in the art should understand that the preferred embodiments are illustrative of the present invention only, but should not be interpreted as restrictive of the scope of the present invention. Hence, all equivalent modifications and changes made to the aforesaid embodiments without departing from the spirit of the present invention should fall within the scope of the present invention.

### BRIEF DESCRIPTION OF THE DRAWINGS

None.

### DETAILED DESCRIPTION OF THE PREFERRED EMBODIMENTS

Objectives, features, and advantages of the present invention are hereunder illustrated with specific embodiments.

As regards the resin composition in embodiments 1 to 4 and comparisons 1 to 2, their ingredients are enumerated in Table 1, and physical properties of said compositions are enumerated in Table 2.

### Embodiment 1 (E1)

Dissolve 5 g of polyphenylene ether pre-polymerized branch cyanate ester (BTP-6020S) in 195 g of toluene to prepare cyanate-toluene solution for later use. Put 100 g of vinyl polyphenylene ether resin (OPE-2st), 20 g of cyclo olefin copolymer (COC 5013), 15 g of 1,2,4-trivinylcyclohexane resin, 90 g of hollow silicon dioxide (B-6C), 10 g of molten silicon dioxide (SC-2050 MB), 0.02 g of zinc octanoate, 40 g of phosphorus-containing flame retardant (OP-935), 1 g of rubber modified resin (Ricon 257), and 2 g of benzoyl peroxide (BPO) in a 1000 mL reaction flask in sequence, and then put a toluene solution of BTP-6020S in the reaction flask, to therefore obtain the resin composition.

### Embodiments 2-4 (E2, E3, E4)

The preparation processes of the resin compositions of embodiments 2-4 are the same as the description in embodiment 1. For ingredients and physical properties of the resin compositions, see Table 1 and Table 2.

Comparison 1 (C1)

Dissolve 40 g of ethylene rubber (Ricon 257) in 160 g of toluene to prepare a 20% toluene solution for later use. Put 100 g of biphenyl epoxy resin (NC-3000H), 26 g of styrene-maleic anhydride copolymer (EF-60), 30 g of benzoxazine (Bz), 90 g of boehmite (AOH60), 10 g of calcinated talc (SG-95), 4 g of dicumyl peroxide (DCP), 25 g of phosphorus-containing flame retardant (OP-935), 0.5 g of adhesive (TSH), and 0.2 g of catalyst (2E4MI) in a 1000 mL reaction flask in sequence, and then put 200 g of ethylene rubber-containing toluene solution in the reaction flask, to therefore obtain the resin composition.

Comparison 2 (C2)

The preparation process of the resin composition of comparison 2 is the same as the description in comparison 1. For ingredients and physical properties of the resin composition, see Table 1 and Table 2.

The resin compositions of embodiments 1-4 and comparisons 1-2 were evenly mixed in a mixing tank by batch and transferred to an impregnation tank. Then, a glass fiber fabric was passed through the impregnation tank to allow the resin composition to be attached to the glass fiber fabric and then undergoing a heating and baking process to become semi-cured, thereby forming a prepreg.

Take four pieces of prepreg mentioned above prepared by the same batch and two pieces of 18-μm copper foils, and stack them in the order of a copper foil, four pieces of prepreg, and a copper foil. Then, the two copper foils and the four pieces of prepreg therebetween were laminated against each other in a vacuum condition and at 220° C. for two hours to form a copper clad laminate, wherein the four pieces of prepreg were cured to form an insulating layer between the two copper foils.

A physical property measurement process was performed on the copper-clad substrate, and a non-copper-containing substrate resulting from a copper foil etching process. The physical property measurement process measures: glass transition temperature Tg, dielectric constant Dk (wherein Dk is the lower the better), dissipation factor Df (wherein Df is the lower the better), copper-clad substrate solder dip (288° C., 10 seconds, to count the times of heat resistance, S/D), and peel strength. The results of measurement of the resin compositions of embodiments 1-4 and comparisons 1-2 are shown in Table 2.

TABLE 1

| ingredient | | E1 | E2 | E3 | E4 | C1 | C2 |
|---|---|---|---|---|---|---|---|
| vinyl polyphenylene | PP-600 | 0 | 100 g | 0 | 0 | 0 | 0 |
| ether resin | MX-9000 | 0 | 0 | 0 | 10 g | 0 | 0 |
| | OPE-2st | 100 g | 0 | 100 g | 90 g | 0 | 0 |
| biphenyl epoxy resin | NC-3000H | 0 | 0 | 0 | 0 | 100 g | 100 g |
| cyclo olefin copolymer | COC 5013 | 20 g | 26 g | 25 g | 25 g | 0 | 0 |
| (COC) | | | | | | | |
| 1,2,4-trivinylcyclohexane | 1,2,4-trivinylcyclohexane | 15 g | 30 g | 30 g | 50 g | 0 | 0 |
| resin | resin | | | | | | |
| Polyphenylene ether | BTP-6020S | 5 g | 10 g | 80 g | 80 g | 0 | 0 |
| pre-polymerized branch | | | | | | | |
| cyanate ester | | | | | | | |
| Benzoxazine | Benzoxazine | 0 | 0 | 0 | 0 | 30 g | 26 g |
| styrene-maleic | EF-60 | 0 | 0 | 0 | 0 | 26 g | 0 |
| anhydride copolymer | | | | | | | |
| calcinated talc | SG-95 | 0 | 0 | 0 | 0 | 10 g | 10 g |
| boehmite | AOH60 | 0 | 0 | 0 | 0 | 90 g | 90 g |
| hollow silicon dioxide | B-6C | 90 g | 90 g | 90 g | 90 g | 0 | 0 |
| molten silicon dioxide | SC-2050MB | 10 g | 10 g | 10 g | 10 g | 0 | 0 |
| phosphorus-containing | SPB-100 | 0 | 45 g | 0 | 0 | 0 | 35 g |
| flame retardant | OP-935 | 40 g | 0 | 35 g | 35 g | 25 g | 0 |
| rubber modified resin | Ricon 257 | 1 g | 1.5 g | 0 | 0 | 40 g | 0 |
| peroxide | BPO | 2 g | 0 | 1 g | 1 g | 0 | 0 |
| | DCP | 0 | 2 g | 1.25 g | 1.25 g | 4 g | 0 |
| zinc octanoate | zinc octanoate | 0.02 g | 0.02 g | 0.04 g | 0.04 g | 0 | 0 |
| diaminodiphenylsulfone | DDS | 0 | 0 | 0 | 0 | 0 | 8 g |
| dicyandiamide | Dicy | 0 | 0 | 0 | 0 | 0 | 0.5 g |
| adhesive | TSH | 0 | 0 | 0 | 0 | 0.5 g | 0 |
| catalyst | 2-ethyl-4-methylimidazole | 0 | 0 | 0 | 0 | 0.2 g | 0.2 g |
| | (2E4MI) | | | | | | |
| solvent | methyl isobutyl ketone | 0 | 0 | 0 | 0 | 0 | 160 g |
| | (MIBK) | | | | | | |
| | Toluene | 195 g | 190 g | 120 g | 120 g | 160 g | 0 |

TABLE 2

| property | test | E1 | | E2 | | E3 | | E4 | | C1 | | C2 | |
|---|---|---|---|---|---|---|---|---|---|---|---|---|---|
| Tg | dynamic | 170° | C. | 175° | C. | 229° | C. | 205° | C. | 145° | C. | 155° | C. |
| | mechanical | | | | | | | | | | | | |
| | analysis | | | | | | | | | | | | |
| | (DMA) | | | | | | | | | | | | |
| Df | 10 GHz | 0.0045 | | 0.0041 | | 0.0042 | | 0.0056 | | 0.0081 | | 0.11 | |
| Dk | 10 GHz | 3.81 | | 3.60 | | 3.68 | | 3.52 | | 4.02 | | 4.13 | |
| S/D | solder dip | >20 | cycle | >20 | cycle | >20 | cycle | >20 | cycle | 10 | cycle | 6 | cycle |
| | 288° C./10 s | | | | | | | | | | | | |

| | | | | | | | |
|---|---|---|---|---|---|---|---|
| peel | Hoz | 7.62 | 6.20 | 6.11 | 5.24 | 7.44 | 6.29 |
| strength | | | | | | | |
| (lb/in) | | | | | | | |

As indicated by the data of embodiments 1-4, all the physical properties of the ingredients of the resin composition of the present invention meet the expected specifications and standards. A comparison of embodiments 1-2 with embodiments 3-4 reveals that embodiments 3-4 feature the use of a relatively larger amount of polyphenylene ether pre-polymerized branch cyanate ester to increase glass transition temperature Tg of the resin composition.

A comparison of embodiments 1-4 with comparisons 1-2 reveals that the resin composition of the present invention manifests satisfactory performance in terms of glass transition temperature, dielectric constant, dissipation factor, heat resistance, and peel strength (wherein, the lower the Dk and Df are, the better the dielectric performance is.)

As described above, the present invention meets the three requirements of patentability, namely novelty, non-obviousness, and industrial applicability. Regarding novelty, and non-obviousness, the halogen-free resin composition of the present invention has the specified ingredient in the specified ratio to attain low dielectric constant (Dk), low dielectric dissipation factor, high glass transition temperature, and high heat resistance, and can be used in preparing a prepreg or a resin film, and is thus applicable to copper clad laminates, and printed circuit boards. Regarding industrial applicability, products derived from the present invention meet market demands fully.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications, and replacements made to the aforesaid embodiments should fall within the scope of the present invention. Accordingly, the legal protection for the present invention should be defined by the appended claims.

What is claimed is:

1. A halogen-free resin composition, comprising:
(A) 100 parts by weight of a polyphenylene ether resin containing an alkenyl group;
(B) 10 to 50 parts by weight of a cyclo olefin copolymer (COC);
(C) 5 to 50 parts by weight of a 1,2,4-trivinylcyclohexane resin and/or a 1,3,5-triethyloxymethyl cyclohexane resin; and
(D) 5 to 150 parts by weight of a polyphenylene ether pre-polymerized branch cyanate ester.

2. The halogen-free resin composition of claim 1, wherein the polyphenylene ether resin containing an alkenyl group is one of the compounds having structures of the following Formula 1, Formula 2, and Formula 3, or the combination thereof: 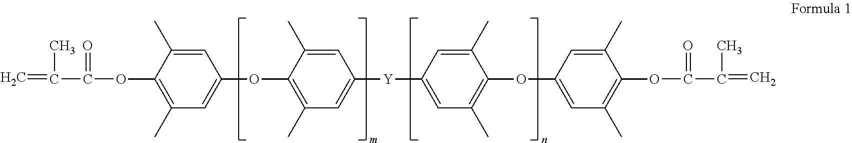
wherein
Y is 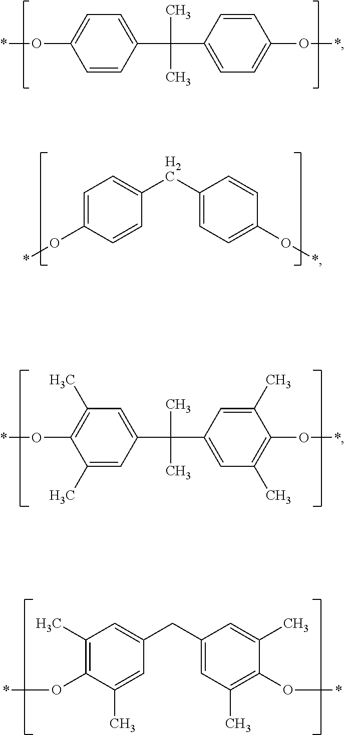
or a covalent bond;
m and n independently represent an integer of 1 or more; 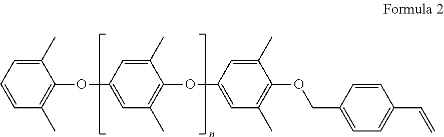
wherein n represents an integer of 6 to 80; 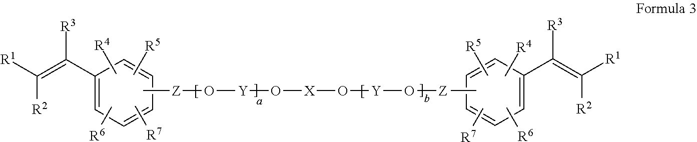
wherein
a and b independently represent an integer of 0 to 30, provided that at least one of a and b is not zero;
R¹, R², R³, R⁴, R⁵, R⁶, and R⁷ independently represent a hydrogen atom, a halogen atom, or an alkyl or phenyl group;
Z represents an organic group containing at least one carbon atom; —(O—X—O)— represents a group having a structure of Formula 4 or Formula 5; 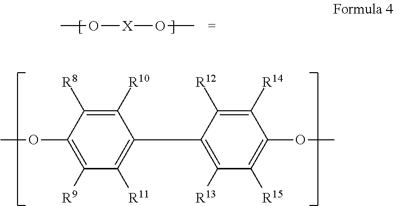
wherein
R⁸, R⁹, R¹⁰, R¹⁴ and R¹⁵ independently represent a halogen atom, an alkyl group containing six or less carbon atoms, or a phenyl group; R¹¹, R¹² and R¹³ independently represent a hydrogen atom, a halogen atom, an alkyl group containing six or less carbon atoms, or a phenyl group; 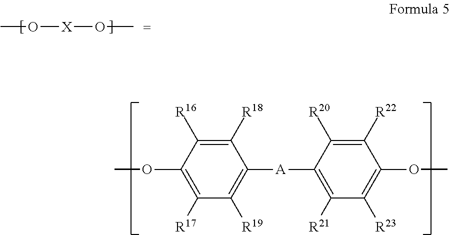
wherein
R¹⁶, R¹⁷, R²², and R²³ independently represent a halogen atom, an alkyl group containing six or less carbon atoms, or a phenyl group; R¹⁸, R¹⁹, R²⁰, and R²¹ independently represent a hydrogen atom, a halogen atom, an alkyl group containing six or less carbon atoms, or a phenyl group; A represents a linear, branched, or cyclic hydrocarbon group containing 20 or less carbon atoms;
—(Y—O)— represents a moiety having a structure of Formula 6 or any rearranged structure thereof; 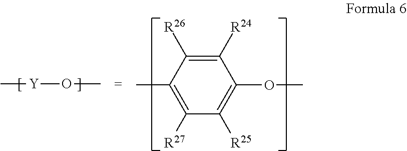
wherein
R²⁴ and R²⁵ independently represent a halogen atom, an alkyl group containing six or less carbon atoms, or a phenyl group;
R²⁶ and R²⁷ independently represent a hydrogen atom, a halogen atom, an alkyl group containing six or less carbon atoms, or a phenyl group.

3. The halogen-free resin composition of claim 1, wherein the cyclo olefin copolymer (COC) has a structure as follows: 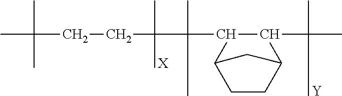
wherein X and Y independently represent an integer of 1 or more.

4. The halogen-free resin composition of claim 1, wherein the polyphenylene ether pre-polymerized branch cyanate ester has a structure as follows: 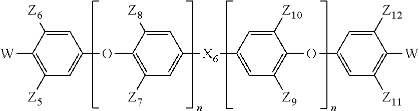
wherein
X₆ represents a covalent bond, —SO₂—, —C(CH₃)₂—, —CH(CH₃)—, or —CH₂—; Z₅ to Z₁₂ independently represent hydrogen or methyl; W represents —O—C≡N, n represents an integer of 1 or more.

5. The halogen-free resin composition of claim 1, further comprising at least one selected from the group consisting of a flame retardant, an inorganic filler, an initiator, a polymerization inhibitor, and an organic solvent.

6. The halogen-free resin composition of claim 5, wherein the flame retardant comprises a phosphate compound and/or a nitrogen-containing phosphate compound.

7. The halogen-free resin composition of claim 6, wherein the amount of the flame retardant is 10 to 250 parts by weight per 100 parts by weight of the polyphenylene ether resin containing an alkenyl group.

8. A prepreg, comprising the resin composition of claim 1.

9. A copper clad laminate, comprising the prepreg of claim 8.

10. A printed circuit board, comprising the copper clad laminate of claim 9.
